(19) United States
(12) Patent Application Publication
(10) Pub. No.: US 2017/0075572 A1
(43) Pub. Date: Mar. 16, 2017

(54) EXTENDING HARDWARE QUEUES WITH SOFTWARE QUEUES

(71) Applicant: SanDisk Technologies Inc., Plano, TX (US)

(72) Inventors: Galya Utevsky, Kfar Saba (IL); Rimma Mazurov, Kfar Saba (IL); Sergey Naiman, Kfar Saba (IL); Alexander Rivman, Kfar Saba (IL); Polina Marimont, Kfar Saba (IL)

(73) Assignee: SANDISK TECHNOLOGIES INC., Plano, TX (US)

(21) Appl. No.: 14/851,833

(22) Filed: Sep. 11, 2015

(51) Int. Cl. G06F 3/06; G06F 13/18; G11C 7/10

(52) U.S. Cl. CPC G06F 3/061; G11C 7/1072; G06F 3/0659; G06F 3/0685; G06F 3/0607; G06F 13/18

(57) ABSTRACT

A storage device with a memory may implement software queueing that can supplement hardware accelerated queueing mechanisms. A software queue supplementing a hardware queue can extend the size and allow pending operations to proceed even if the hardware queue is saturated. The use of software-based queues may extend processing capacity in a hardware-accelerated front-end storage device architecture. The software queue may process excess commands that cannot be handled by a hardware queue with a limited depth.

### TECHNICAL FIELD

This application relates generally to memory devices. More specifically, this application relates to using software-based queues in a memory system.

### BACKGROUND

Non-volatile memory systems, such as flash memory, have been widely adopted for use in consumer products. Flash memory may be found in different forms, for example in the form of a portable memory card that can be carried between host devices or as a solid state disk (SSD) embedded in a host device. The flash device controller receives commands, such as read commands, from a host. The commands may include admin (e.g. commands for device configuration and maintenance) as well as operation commands (e.g. commands for accessing the NAND media including erase, write and read commands). There may be a hardware queue for when the controller has many commands waiting for execution. However, when the hardware queue is saturated with too many commands, performance of the memory may suffer because the commands are not executed promptly. Complex protocols such as Non-Volatile Memory Express (NVMe) may require hardware accelerated queuing mechanisms in order to deliver optimal performance. However, these hardware engines may have limited and hard coded queue sizes (i.e. limited queue depths). With a limited depth of the hardware queue, the queue may overflow more often causing performance issues. Further, due to a demand in higher performance storage is coming from a various range of applications such as cloud computing, high performance computing and video broadcasting, there is a need for improved performance regarding the hardware queue.

### SUMMARY

Given the potential limitations of the command queue in hardware, it may be advantageous to move some of the processing to a software queue. A software queue supplementing a hardware queue can extend the size and allow pending operations to proceed even if the hardware queue is saturated. By using software queues, the internal hardware queue size may be reduced in a cost-sensitive product. Accordingly, the use of software-based queues may extend processing capacity in a hardware-accelerated front-end storage device architecture. In addition, high queue depths may be necessary for several benchmarks. In order to avoid a high queue depth saturating the hardware queues and limiting overall performance, the excess commands may be processed with the software queue.

In one embodiment, a storage device includes a memory and a controller configured to use a hardware queue for incoming commands. A random access memory stores a software queue and a command parser parses commands from the hardware queue and the software queue. The commands are added to the software queue concurrently with a processing of those commands.

In another embodiment, a method for utilizing a software queue with a hardware queue for a memory system includes receiving a command from a host and determining whether a hardware queue of commands from the host is full. When the queue is not full, the received command is added to the hardware queue. When the queue is full, the received command is added to the software queue. The command is processed concurrently with being added to the software queue. The processing comprises executing the commands and waiting for execution of the commands.

In another embodiment, a memory controller includes a random access memory for storing a software queue that supplements a hardware queue that stores commands from a host. A command parser parses commands from both the hardware queue and the software queue, and a queue arbiter prioritizes commands in both the hardware queue and the software queue. A command executer executes commands based on the prioritization, wherein execution of a command is concurrent with adding that command to the software queue.

### BRIEF DESCRIPTION OF THE DRAWINGS

FIG. 1A is a block diagram of an example non-volatile memory system.

FIG. 1B is a block diagram of a storage module that includes a plurality of non-volatile memory systems.

FIG. 1C is a block diagram of a hierarchical storage system.

FIG. 2A is a block diagram of exemplary components of a controller of a non-volatile memory system.

FIG. 2B is a block diagram of exemplary components of a non-volatile memory of a non-volatile memory storage system.

FIG. 3 is a block diagram of a flash device controller.

FIG. 4 is a timing diagram of a page read operation.

FIG. 5 is a flow chart of command processing.

FIG. 6 is a flow chart of a read command which may be concurrent with maintaining the queue entry in a software queue.

### DESCRIPTION OF THE EMBODIMENTS

The software queueing mechanism described herein may be used within an architecture or protocol that supports queueing, such as protocols that utilize hardware accelerated queueing mechanisms. One example of such a memory protocol is Non-Volatile Memory Express (NVMe). NVMe is merely one example of a protocol that utilizes queueing and other protocols are possible. For simplicity, the software queueing described below may refer to NVMe, but may apply to many other protocols or architectures. NVMe may reduce latency and provide faster performance with support for security and end-to-end data protection and provide a flexible architecture for Enterprise and Client platforms. NVMe is merely one example of a host controller interface with a register interface and command set which may be applicable to systems that use Peripheral Component Interconnect Express (PCIe) solid state discs (SSDs). NVMe may include multi-queue based communication with host and controllers writing to submission and completion queues in host memory. NVMe is a submission/completion queue-based protocol where commands are created by the host and placed in a submission queue. A completion queue may signal to the host that the commands have been executed. When a submission command is ready in the submission queue, the device fetches the submission command from the host memory. The submission command may be executed according to its priority defined with an arbitration scheme.

Queues may be used in multithreaded programs for synchronization and communication. Because software queues may be too expensive to support fine grained parallelism, hardware queues may be used to reduce overhead of communication between cores. As described herein, a software queue may be used to supplement a hardware queue for maximizing performance and ensuring that a small depth hardware queue will not hinder performance. The software queues may be in dynamic memory for extending the size of the hardware queue. To leverage the hardware engine, completion events may still be pushed back to the hardware queue from the software queues. Accordingly, the software queues may be used for specific purposes with certain commands.

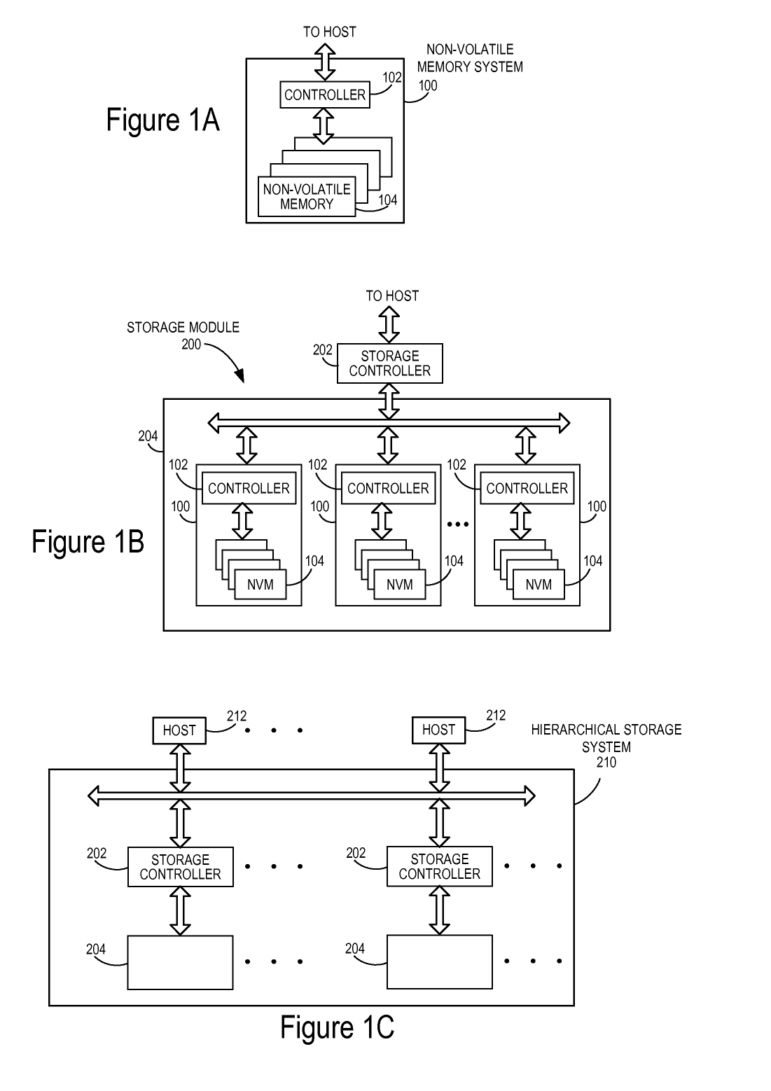

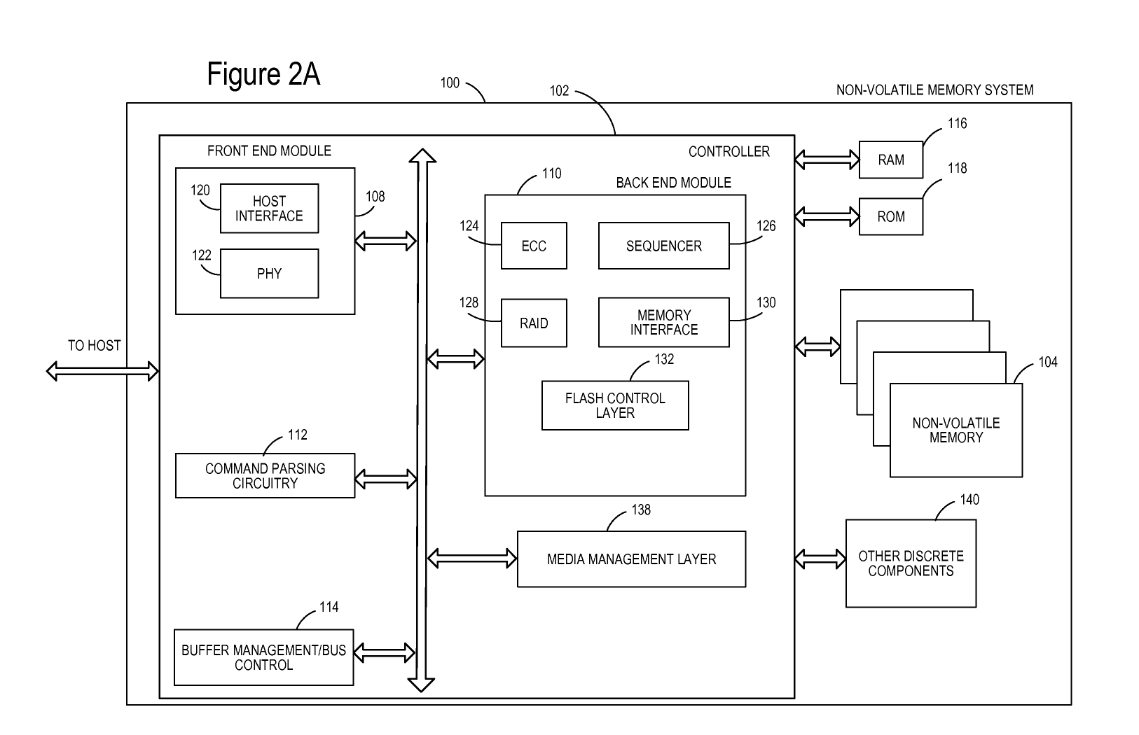

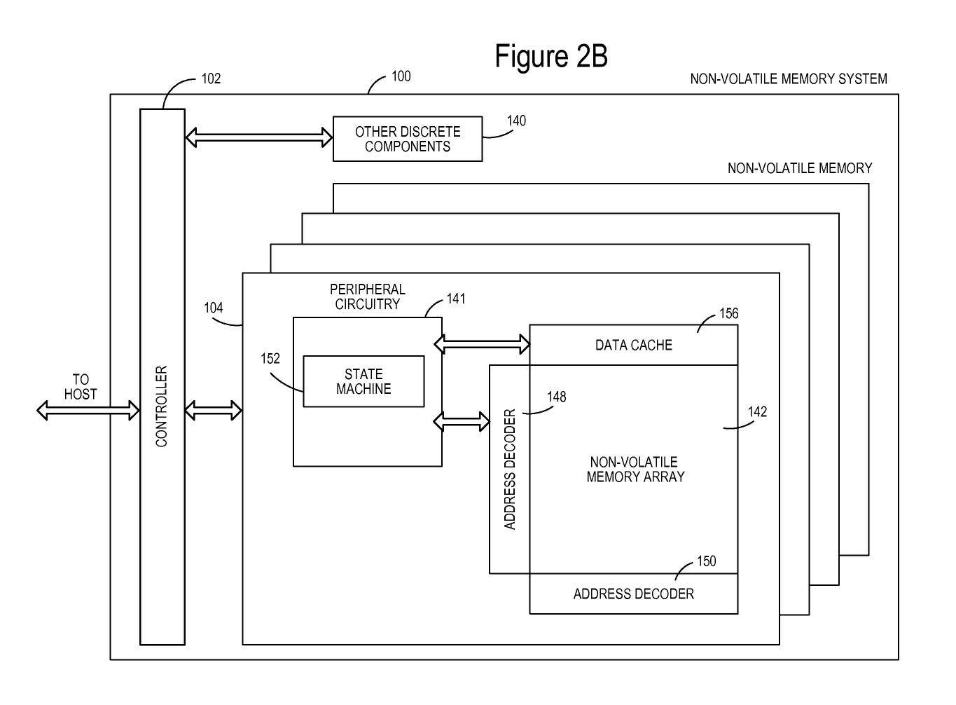

FIGS. 1A-2B are exemplary memory systems which may implement software queueing that can supplement hardware accelerated queueing mechanisms. FIG. 1A is a block diagram illustrating a non-volatile memory system. The non-volatile memory system 100 includes a controller 102 and non-volatile memory that may be made up of one or more non-volatile memory die 104. As used herein, the term die refers to the set of non-volatile memory cells, and associated circuitry for managing the physical operation of those non-volatile memory cells, that are formed on a single semiconductor substrate. Controller 102 interfaces with a host system and transmits command sequences for read, program, and erase operations to non-volatile memory die 104. The non-volatile memory die 104 may store an operating system for the host.

Examples of host systems include, but are not limited to, personal computers (PCs), such as desktop or laptop and other portable computers, tablets, mobile devices, cellular telephones, smartphones, personal digital assistants (PDAs), gaming devices, digital still cameras, digital movie cameras, and portable media players. For portable memory card applications, a host may include a built-in receptacle for one or more types of memory cards or flash drives, or a host may require adapters into which a memory card is plugged. The memory system may include its own memory controller and drivers but there may also be some memory-only systems that are instead controlled by software executed by the host to which the memory is connected. In some memory systems containing the controller, especially those embedded within a host, the memory, controller and drivers are often formed on a single integrated circuit chip. The host may communicate with the memory card using any communication protocol such as but not limited to Secure Digital (SD) protocol, Memory Stick (MS) protocol and Universal Serial Bus (USB) protocol.

The controller 102 (which may be a flash memory controller or device controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, a flash memory controller is a device that manages data stored on flash memory and communicates with a host, such as a computer or electronic device. A flash memory controller can have various functionality in addition to the specific functionality described herein. For example, the flash memory controller can format the flash memory to ensure the memory is operating properly, map out bad flash memory cells, and allocate spare cells to be substituted for future failed cells. Some part of the spare cells can be used to hold firmware to operate the flash memory controller and implement other features. In operation, when a host needs to read data from or write data to the flash memory, it will communicate with the flash memory controller. If the host provides a logical address to which data is to be read/written, the flash memory controller can convert the logical address received from the host to a physical address in the flash memory. (Alternatively, the host can provide the physical address). The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 104 may include any suitable non-volatile storage medium, including NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory cell level technologies, now known or later developed. Also, the memory cells can be fabricated in a two-dimensional or three-dimensional fashion.

The interface between controller 102 and non-volatile memory die 104 may be any suitable flash interface, such as Toggle Mode 200, 400, or 800. In one embodiment, memory system 100 may be part of an embedded memory system. For example, the flash memory may be embedded within the host, such as in the form of a solid state disk (SSD) drive installed in a personal computer. In another embodiment, memory system 100 may be a card based system, such as a secure digital (SD) or a micro secure digital (micro-SD) card.

Although in the example illustrated in FIG. 1A, non-volatile memory system 100 includes a single channel between controller 102 and non-volatile memory die 104, the subject matter described herein is not limited to having a single memory channel. For example, in some NAND memory system architectures, such as in FIGS. 1B and 1C, 2, 4, 8 or more NAND channels may exist between the controller and the NAND memory device, depending on controller capabilities. In any of the embodiments described herein, more than a single channel may exist between the controller and the memory die, even if a single channel is shown in the drawings.

FIG. 1B illustrates a storage module 200 that includes plural non-volatile memory systems 100. As such, storage module 200 may include a storage controller 202 that interfaces with a host and with storage system 204, which includes a plurality of non-volatile memory systems 100. The interface between storage controller 202 and non-volatile memory systems 100 may be a bus interface, such as a serial advanced technology attachment (SATA) or peripheral component interface express (PCIe) interface. Storage module 200, in one embodiment, may be a solid state drive (SSD), such as found in portable computing devices, such as laptop computers, and tablet computers.

FIG. 1C is a block diagram illustrating a hierarchical storage system. A hierarchical storage system 210 includes a plurality of storage controllers 202, each of which control a respective storage system 204. Host systems 212 may access memories within the hierarchical storage system via a bus interface. In one embodiment, the bus interface may be a non-volatile memory express (NVMe) or a fiber channel over Ethernet (FCoE) interface. In one embodiment, the system illustrated in FIG. 1C may be a rack mountable mass storage system that is accessible by multiple host computers, such as would be found in a data center or other location where mass storage is needed.

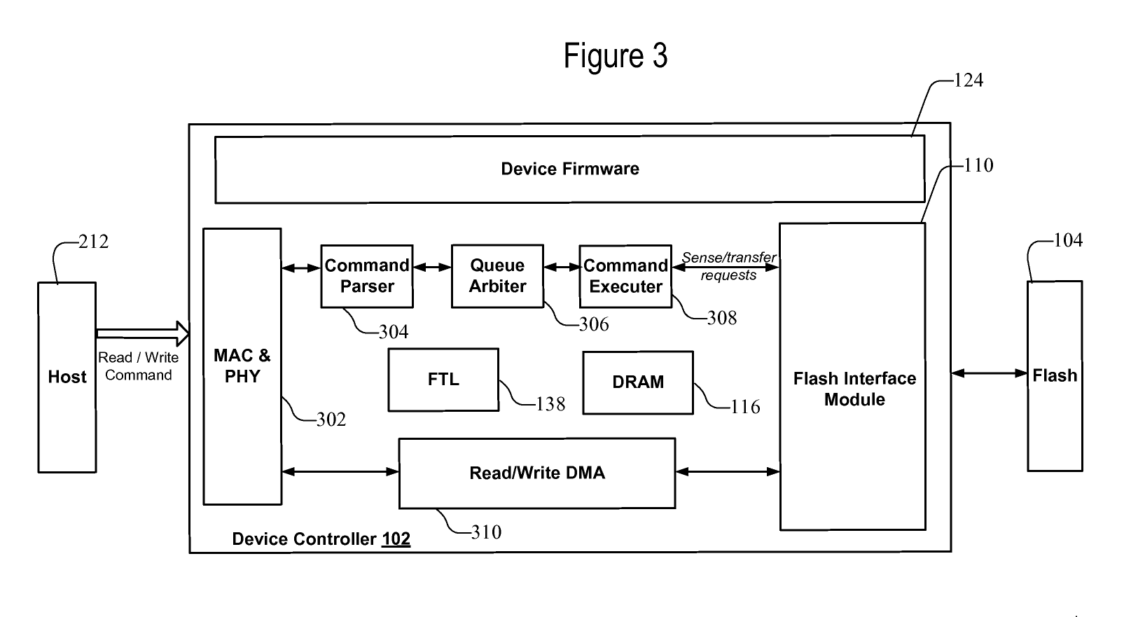

FIG. 2A is a block diagram illustrating exemplary components of controller 102 in more detail. Controller 102 includes a front end module 108 that interfaces with a host, a back end module 110 that interfaces with the one or more non-volatile memory die 104, and various other modules that perform functions which will now be described in detail. The front end module 108 may include the command parser 304, queue arbiter 306, and/or command executor 308 as shown in and described with respect to FIG. 3.

A module may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively or in addition, each module may include memory hardware, such as a portion of the memory 104, for example, that comprises instructions executable with a processor to implement one or more of the features of the module. When any one of the modules includes the portion of the memory that comprises instructions executable with the processor, the module may or may not include the processor. In some examples, each module may just be the portion of the memory 104 or other physical memory that comprises instructions executable with the processor to implement the features of the corresponding module.

The controller 102 may include command parsing circuitry 112. The command parsing circuitry 112 may receive and parse commands with a queue. The command parsing circuitry 112 may utilize a software queue in addition to the hardware queue as further described with respect to FIGS. 3-6. The command parsing circuitry 112 may include a command parser, queue manager/arbiter, and/or a command executor for processing commands and managing the queue as further illustrated in FIG. 3.

Referring again to modules of the controller 102, a buffer manager/bus controller 114 manages buffers in random access memory (RAM) 116 and controls the internal bus arbitration of controller 102. A read only memory (ROM) 118 stores system boot code. Although illustrated in FIG. 2A as located separately from the controller 102, in other embodiments one or both of the RAM 116 and ROM 118 may be located within the controller. In yet other embodiments, portions of RAM and ROM may be located both within the controller 102 and outside the controller. Further, in some implementations, the controller 102, RAM 116, and ROM 118 may be located on separate semiconductor die.

Front end module 108 includes a host interface 120 and a physical layer interface (PHY) 122 that provide the electrical interface with the host or next level storage controller. The choice of the type of host interface 120 can depend on the type of memory being used. Examples of host interfaces 120 include, but are not limited to, SATA, SATA Express, SAS, Fibre Channel, USB, PCIe, and NVMe. The host interface 120 typically facilitates transfer for data, control signals, and timing signals. As described herein, the software queueing mechanism may be used with a host interface that includes queueing and utilizes a hardware arbitration mechanism.

Back end module 110 includes an error correction controller (ECC) engine 124 that encodes the data bytes received from the host, and decodes and error corrects the data bytes read from the non-volatile memory. A command sequencer 126 generates command sequences, such as program and erase command sequences, to be transmitted to non-volatile memory die 104. A RAID (Redundant Array of Independent Drives) module 128 manages generation of RAID parity and recovery of failed data. The RAID parity may be used as an additional level of integrity protection for the data being written into the non-volatile memory system 100. In some cases, the RAID module 128 may be a part of the ECC engine 124. A memory interface 130 provides the command sequences to non-volatile memory die 104 and receives status information from non-volatile memory die 104. In one embodiment, memory interface 130 may be a double data rate (DDR) interface, such as a Toggle Mode 200, 400, or 800 interface. A flash control layer 132 controls the overall operation of back end module 110.

Additional components of system 100 illustrated in FIG. 2A include media management layer 138, which performs wear leveling of memory cells of non-volatile memory die 104. System 100 also includes other discrete components 140, such as external electrical interfaces, external RAM, resistors, capacitors, or other components that may interface with controller 102. In alternative embodiments, one or more of the physical layer interface 122, RAID module 128, media management layer 138 and buffer management/bus controller 114 are optional components that are not necessary in the controller 102.

The FTL or MML 138 may be integrated as part of the flash management that may handle flash errors and interfacing with the host. In particular, MML may be a module in flash management and may be responsible for the internals of NAND management. In particular, the MML 138 may include an algorithm in the memory device firmware which translates writes from the host into writes to the flash memory 104. The MML 138 may be needed because: 1) the flash memory may have limited endurance; 2) the flash memory 104 may only be written in multiples of pages; and/or 3) the flash memory 104 may not be written unless it is erased as a block. The MML 138 understands these potential limitations of the flash memory 104 which may not be visible to the host. Accordingly, the MML 138 attempts to translate the writes from host into writes into the flash memory 104. As described below, erratic bits may be identified and recorded using the MML 138. This recording of erratic bits can be used for evaluating the health of blocks.

FIG. 2B is a block diagram illustrating exemplary components of non-volatile memory die 104 in more detail. Non-volatile memory die 104 includes peripheral circuitry 141 and non-volatile memory array 142. Non-volatile memory array 142 includes the non-volatile memory cells used to store data and may be arranged in planes. In one embodiment, each non-volatile memory die 104 may include one or more planes. The non-volatile memory cells may be any suitable non-volatile memory cells, including NAND flash memory cells and/or NOR flash memory cells in a two dimensional and/or three dimensional configuration. Peripheral circuitry 141 includes a state machine 152 that provides status information to controller 102. Non-volatile memory die 104 further includes a data cache 156 that caches data. Exemplary peripheral circuitry 141 may include clocks, pumps, ESD, current shunt, current sink, and/or closely-packed logic circuits.

FIG. 3 may be a portion of FIG. 1 or may illustrate an alternative embodiment. FIG. 3 illustrates an alternative embodiment of the device controller 102, its internal block and their interactions. The host 212 sends commands to the device controller 102 using a physical interface which connects the host to the memory device controller 102. There are many protocols defined in the industry for this interface such as Peripheral Component Interconnect Express (PCIe), SATA and etc. Although any interface or any protocol may be implemented, for purposes of this application, the PCIe interface may be described. The MAC and PHY 302 implement three low protocol layers (Transaction layer, Data Link layer and Physical layer). The responsibility for the MAC and PHY 302 may be to make sure that packets are transferred between the host 212 and the memory device controller 102 without the errors defined in those layers.

The command parser 304 receives the operation as well as the admin host commands, parses them and checks the correctness of the host commands. It may interact with the queue arbiter/manager 306 in order to queue the commands to the appropriate queue. Before executions, host commands may be pending with the queue arbiter 306. The queue arbiter may be an arbitration mechanism for prioritizing commands to be executed by the command executor 308. There may be numerous read and write accesses simultaneously, which may require management through an arbitration mechanism provided by the queue arbiter 306. One exemplary arbitration mechanism is round robin or weighted round robin, which may be used for NVMe in one example. The arbitration mechanism may be used to determine priority of commands in the queue for ensuring that high priority commands are queued for execution before lower priority commands. The command parser 304 or the queue arbiter 306 may be responsible for controlling the flow of data between the controller and the device by ordering requests or commands in the queue. The order may be based on priority of the request, availability of resources to handle the request, an address need for the request, age of the request, or access history of the requestor.

A command queue 312 is a queue for enabling the delay of command execution, either in order of priority, on a first-in first-out basis, or in any other order. Instead of waiting for each command to be executed before sending the next one, the program just puts the commands in the queue and can perform other processes while the queue is executed. A queue may be used to control the flow of data between the controller and the device. Commands may be placed in the command queue 312 and ordered by the queue arbiter 306. The order may be based on priority of the request, availability of resources to handle the request, an address need for the request, age of the request, or access history of the requestor. Although not shown in FIG. 3, the command parser 304, queue arbiter 306, and the command executer 308 may be a part of the host interface module (HIM), such as the host interface 120 shown in FIG. 2A which is part of the front end 108. In addition, the HIM may include the MAC & PHY 302.

Command executer 308 may be responsible for command selection and execution. Pending commands may be arbitrated by the queue arbiter 306 to select the next command for execution by sending sense and transfer requests to the flash interface module (“FIM”) 110. In one embodiment, the FIM 110 may generate the sense/transfer or program operations to the flash 104. FIM 110 interacts with the flash memory 104 by sending flash commands. In one embodiment, the software queue of flash commands may be stored in dynamic random access memory (DRAM) 116 while the hardware queue may be part of the HIM.

The flash management from the flash transformation layer (FTL) 138 may be responsible for internal memory management operations such as address translation. The FTL 138 may also be referred to as the media management layer (MML). The device controller may include a read/write direct memory access (“DMA”) 310 which may be responsible for transferring data between the host and the device. The command parser 304, queue arbiter/manager 306, flash management 138 and command executer 308 may be responsible for handling the control path in the device, while the read/write DMA 310 handles the data path in the device. Device firmware 124 may control and manage the functionality of this logic. At the initialization phase, the firmware may configure the device controller 102. During operation, the firmware 124 controls the logic and manages the flash memory 104. The firmware 124 may also assist with the command parsing and queue storage and access.

In one embodiment, command executer 308 may queue sense and transfer requests to the flash commands queue 312. FIM 110 may use this information for sending commands to the flash memory 116. The sense/transfer requests may include other parameters that assist FIM 110. For example, sense requests may include the flash address while transfer requests may include the amount of data to be read from the flash memory 104.

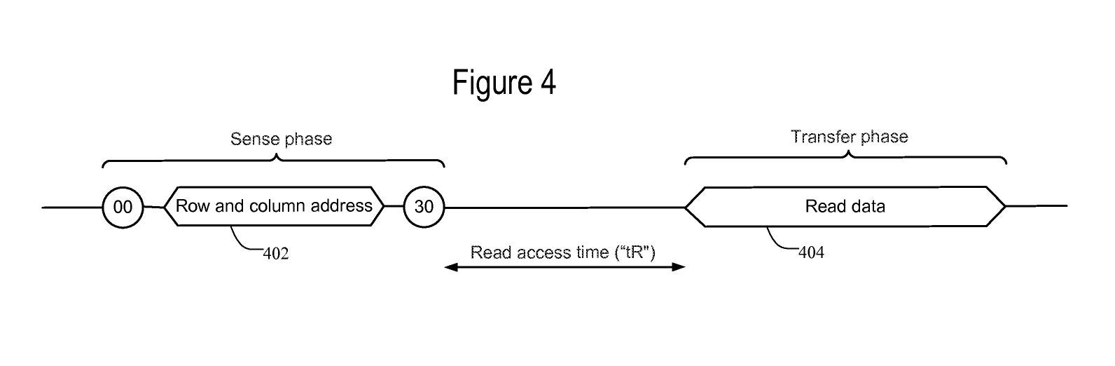

FIG. 4 is a timing diagram of page read operation. A page read operation includes a sense phase and a transfer phase for each read. The sense phase includes an identification of the row and column address 402. In particular, the flash interface provides the row and column address, then it waits the read access time (tR) before the data is read 404 for the transfer phase. The read access time tR is the time between when the row and column address are known until the data is actually read.

In NAND flash memory embodiments, there may be eight I/O pins. Command, address, and data may all be written through those I/O pins. There are many commands supported by the flash and each command may start by driving a special code on the I/O interface and may end by driving another special code on that interface. For example, the page read operation may start with the host controller driving 00 on the I/O path, and then provide the row and the column address and finally terminating the command by driving 30 on this path. The 00 represents the starting special code of page read command. Next, the device controller drives the row and the column address. Finally, the device controller ends the command by driving the 30 special code on that interface. With respect to the command queue, the command may be queued such that the sense phase is pending in the queue.

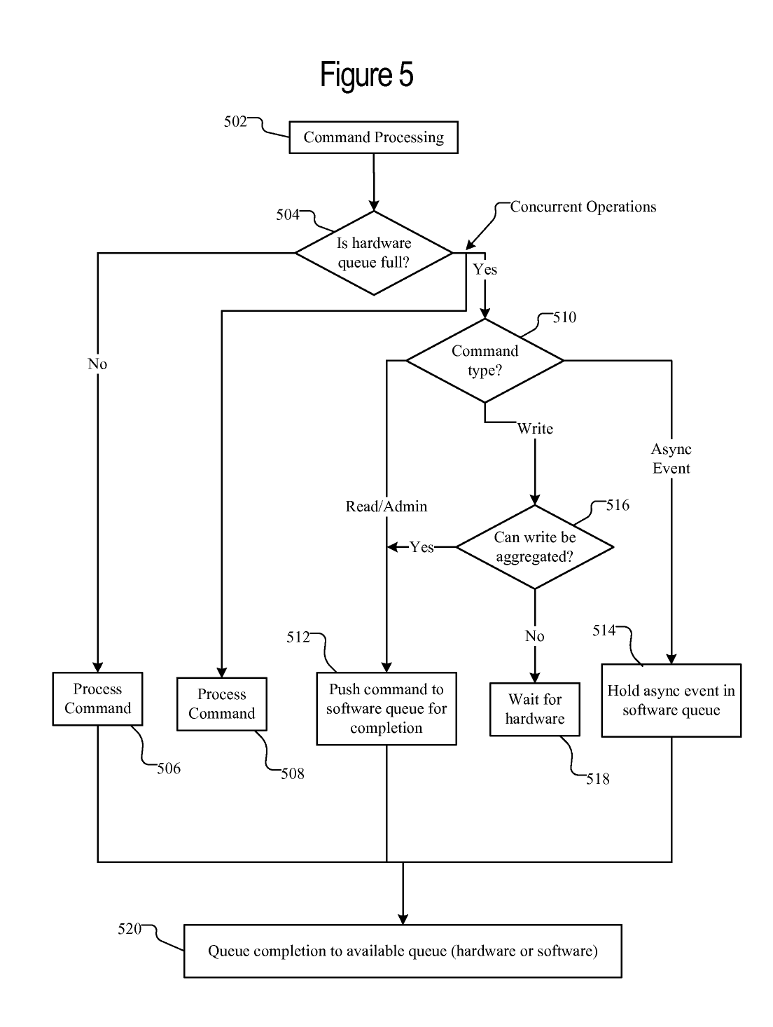

FIG. 5 is a flow chart of command processing. The command processing may be through the command parser 304 which accesses a software queue from the DRAM 116. The commands are pulled from the hardware queue in arbitration order as discussed above with respect to the queue arbiter 306. The command processing begins in block 502. Initially, a check is performed to determine whether the hardware queue is full in block 504. If the hardware queue is not full in block 504, then the command can be processed in block 506. Command processing may include an execution process of the command. The execution of the command may require that the command remain in the queue until the execution fully completes. If the hardware queue is full in block 504, then the command is processed in block 508 concurrently with the process that begins with determining the command type in block 510. In other words, the hardware queue arbiter 306 pulls the command out and it may be added into the software queue. If there are free resources to begin executing the command, it is executed otherwise it stays in the queue until there are resources to execute it.

The processing of the command concurrent with the adding of the command to the software queue may allow for the firmware to decide the most efficient execution of the command. While the command is executed/processed, the command remains in the queue. In this instance, the command is added to the software queue while being executed or while waiting to be executed. Based on the depth limits of the hardware queue, it may be more efficient for the command to be stored in the software queue, while it is being executed. Otherwise, the command would take up space in the hardware queue during execution.

The command types determined in block 510 may include a read or admin command, a write command, or an asynchronous event command. There are other types of commands that may be considered, but those three commands are exemplary. For a read command or an admin command, the command is pushed to the software queue for completion in block 512. Administration submission commands may include: Delete I/O Submission Queue, Create I/O Submission Queue, Get Log Page, Delete I/O Completion Queue, Create I/O Completion Queue, Identify, Abort, Set Features, Get Features, Asynchronous Event Request, Firmware Activate, Firmware Image Download, I/O Command Set specific, Format NVM, Security Send, and Security Receive. Read and write may be exemplary input/output submission commands, along with a flush command.

For a write command, a determination is made as to whether the write can be aggregated in block 516. If the write can be aggregated, then it may be pushed to the software queue in block 512. If the write command cannot be aggregated in block 516, then the command will wait for the hardware queue for this command as in block 518. If the command type on block 510 is an asynchronous event, then the asynchronous event may be held in the software queue as in block 514. After the blocks 506, 508, 512, 514, the completion of the command is sent to the correct queue (hardware or software) to signal completion of the command in block 520. In one embodiment, there may be a completion queue that includes a status for completed commands.

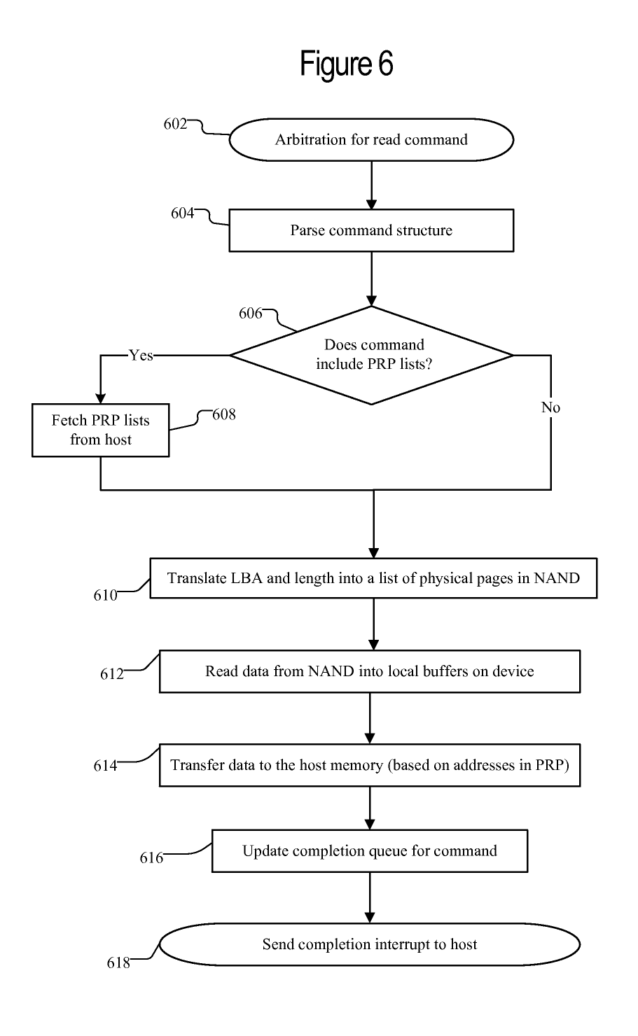

FIG. 6 is a flow chart of a read command which may be concurrent with maintaining the queue entry in a software queue. In an alternative embodiment, similar steps may work for a write command, with the data flow in the other direction (the write may complete before data is written to NAND, as long as it is within device memory). In block 602, the arbitration for the read command is performed. The arbitration may include ordering or prioritizing commands from the queue(s) based on the characteristics of each queue. For example, the NVMe standard may include Weighted Round Robin with Urgent Class arbitration as well as the ability to use vendor specific algorithms, in addition to the arbitration burst, to determine how many commands to take from each queue in an arbitration cycle. In block 604, the command structure may be parsed to determine if the command includes Physical Region Page (PRP) lists as in block 606. The physical memory locations in host memory to use for data transfers may be specified by PRP lists. The PRP list may be fetched from the host in block 608. In one embodiment, a pointer to a PRP list with PRP entries may be provided. If the command does not include PRP lists in block 606, then the fetch from the host is skipped, and the physical memory address range described in the PRP is used as a target for the read. The logical block addresses and length are translated into a list of physical pages in NAND as in block 610. The data form the NAND is read into local buffers on the device in block 612. The data is transferred to the host memory based on the addresses in PRP in block 614. Blocks 612 and 614 may be executed multiple times based on the size of the local buffer in the device until all data specified in the command was written to host physical memory. The completion queue is updated for this command in block 616 and the completion interrupt is provided to the host in block 618.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art.

In the present application, semiconductor memory devices such as those described in the present application may include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magneto-resistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

A “computer-readable medium,” “machine readable medium,” “propagated-signal” medium, and/or “signal-bearing medium” may comprise any device that includes, stores, communicates, propagates, or transports software for use by or in connection with an instruction executable system, apparatus, or device. The machine-readable medium may selectively be, but not limited to, an electronic, magnetic, optical, electromagnetic, infrared, or semiconductor system, apparatus, device, or propagation medium. A non-exhaustive list of examples of a machine-readable medium would include: an electrical connection “electronic” having one or more wires, a portable magnetic or optical disk, a volatile memory such as a Random Access Memory “RAM”, a Read-Only Memory “ROM”, an Erasable Programmable Read-Only Memory (EPROM or Flash memory), or an optical fiber. A machine-readable medium may also include a tangible medium upon which software is printed, as the software may be electronically stored as an image or in another format (e.g., through an optical scan), then compiled, and/or interpreted or otherwise processed. The processed medium may then be stored in a computer and/or machine memory. In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

It is intended that the foregoing detailed description be understood as an illustration of selected forms that the invention can take and not as a definition of the invention. It is only the following claims, including all equivalents that are intended to define the scope of the claimed invention. Finally, it should be noted that any aspect of any of the preferred embodiments described herein can be used alone or in combination with one another.

We claim:

1. A storage device comprising:
a memory comprising a plurality of blocks;
a controller coupled with the memory that is configured to use a hardware queue for incoming commands; and
a random access memory coupled with the controller and configured to store a software queue; and
a command parser for parsing commands from the hardware queue and the software queue, wherein commands are added to the software queue concurrently with a processing of those commands.

2. The storage device of claim 1 wherein the processing of those commands comprises waiting for execution and execution of those commands.

3. The storage device of claim 1 wherein the software queue includes read commands, admin commands, and asynchronous commands.

4. The storage device of claim 3 wherein a write command is put into the hardware queue except when the write command can be aggregated, in which case the write command is put into the software queue.

5. The storage device of claim 1 further comprising:
an arbitration mechanism that prioritizes commands from both the hardware queue and the software queue.

6. The storage device of claim 5 wherein the arbitration mechanism comprises a queue arbiter that is part of the controller and the command parser parses commands based on the prioritization from the arbitration mechanism.

7. The storage device of claim 1 wherein the command parser comprises command parser circuitry within the controller, and wherein the random access memory is part of the controller.

8. The storage device of claim 1 wherein the random access memory comprises a dynamic random access memory that stores the software queue when the hardware queue is full.

9. The storage device of claim 1 wherein the memory comprises a three-dimensional (3D) memory configuration, and wherein a controller is associated with operation of and storing to the flash memory.

10. A method for utilizing a software queue with a hardware queue for a memory system, the method comprising:
receiving a command from a host;
determining whether a hardware queue of commands from the host is full;
adding, when the hardware queue is not full, the received command to the hardware queue;
adding, when the hardware queue is full, the received command to a software queue;
processing, concurrently with the adding to the software queue, the commands, wherein the processing comprises executing the commands and waiting for execution of the commands.

11. The method of claim 10 further comprising:
parsing the commands from both the hardware queue and the software queue.

12. The method of claim 11 wherein the software queue is stored in dynamic memory and the parsing is from a front end command parser.

13. The method of claim 10 wherein an internal size of the hardware queue is reduced because of utilization of the software queue.

14. The method of claim 10 further comprising:
prioritizing, with an arbitration mechanism, commands from both the hardware queue and the software queue; and
selecting commands for the processing based on the prioritizing.

15. The method of claim 10 further comprising:
utilizing the hardware queue for completion events; and
utilizing the software queue for read commands, admin commands, and asynchronous commands.

16. A memory controller comprising:
a random access memory for storing a software queue, wherein the software queue supplements a hardware queue that stores commands from a host;
a command parser that parses commands from both the hardware queue and the software queue; and
a queue arbiter that prioritizes commands in both the hardware queue and the software queue; and
a command executer that executes commands based on the prioritization, wherein execution of a command is concurrent with adding that command to the software queue.

17. The memory controller of claim 16 wherein execution of the command comprises waiting for the execution.

18. The memory controller of claim 17 wherein the command is maintained in the software queue while waiting for the execution.

19. The memory controller of claim 16 wherein the memory controller is coupled with flash memory.

20. The memory controller of claim 16 wherein the hardware queue is stored in a front end of the memory controller and the queue arbiter comprises an arbitration mechanism.
